(19) United States
(12) Patent Application Publication
(10) Pub. No.: US 2024/0367129 A1
(43) Pub. Date: Nov. 7, 2024

(54) FEEDSTOCK SUPPLY DEVICE

(71) Applicant: TOKYO ELECTRONIC LIMITED, Tokyo (JP)

(72) Inventor: Eiichi KOMORI, Aichi (JP)

(21) Appl. No.: 18/687,266

(22) PCT Filed: Aug. 25, 2022
(86) PCT No.: PCT/JP2022/032015

§ 371 Date: Feb. 27, 2024

(30) Foreign Application Priority Data
Sep. 8, 2021 (JP) 2021-146294

(51) Int. Cl. B01J 7/02; B01J 4/00; B05B 15/00

(52) U.S. Cl. CPC B01J 7/02; B01J 4/002; B05B 15/00; B01J 2204/007; B01J 2219/2474

(57) ABSTRACT

A feedstock supply device according to one aspect of the present disclosure produces a reactive gas from a solution in which a solid feedstock has been dissolved in a solvent or from a dispersion system in which a solid feedstock has been dispersed into a dispersion medium. This feedstock supply device comprises: a container having a first wall surface forming an internal space; a spray nozzle for spraying the solution or the dispersion system into the internal space; and a wall structure provided to the internal space and having a second wall surface extending in the vertical direction.

### TECHNICAL FIELD

The present disclosure relates to a raw material supply device.

### BACKGROUND

There is known a technique for dissolving a solid raw material in a solvent and spraying it into a processing chamber, and then heating the processing chamber to remove the solvent and allow the solid raw material to remain, and then heating the processing chamber to sublimate the solid raw material to thereby generate a gas corresponding thereto (see, e.g., Patent Documents 1 and 2).

### PRIOR ART DOCUMENTS

### Patent Documents

Patent Document 1: Japanese Laid-open Patent Publication No. 2004-115831
Patent Document 2: Japanese Laid-open Patent Publication No. 2009-170800

### SUMMARY

### Problems to Be Resolved by the Invention

The present disclosure provides a technique capable of sublimating a solid raw material and supplying it to a processing chamber at a large flow rate.

### Means for Solving the Problems

In accordance with one embodiment of the present disclosure, there is provided a raw material supply device for producing a reactive gas from a solution in which a solid raw material is dissolved in a solvent or from a dispersion system in which a solid raw material is dispersed in a dispersion medium, comprising: a container having a first wall surface forming an inner space; a spray nozzle configured to spray the solution or the dispersion system into the inner space; and a wall structure disposed in the inner space and having a second wall surface extending in a vertical direction.

### Effect of the Invention

In accordance with the present disclosure, when a solid raw material is sublimated and supplied to a processing container, it can be supplied at a large flow rate.

### BRIEF DESCRIPTION OF THE DRAWINGS

FIG. 1 shows an example of a raw material supply system according to an embodiment.

FIG. 2A shows an example of a raw material supply device.

FIG. 2B show an example of the raw material supply device.

FIG. 3 explains the operation of the raw material supply system of FIG. 1.

FIG. 4 explains the operation of the raw material supply system of FIG. 1.

FIG. 5 explains a spraying process of a raw material supply method according to an embodiment.

FIG. 6 explains a drying process of the raw material supply method according to the embodiment.

FIG. 7 explains a sublimation process of the raw material supply method according to the embodiment.

FIG. 8A shows a first modification of the raw material supply device.

FIG. 8B shows the first modification of the raw material supply device.

FIG. 9A shows a second modification of the raw material supply device.

FIG. 9B shows the second modification of the raw material supply device.

FIG. 9C shows the second modification of the raw material supply device.

### DETAILED DESCRIPTION

Hereinafter, non-limiting exemplary embodiments of the present disclosure will be described with reference to the accompanying drawings. Like reference numerals will be given to like or corresponding parts or components throughout the drawings, and redundant description thereof will be omitted.

### Raw Material Supply System

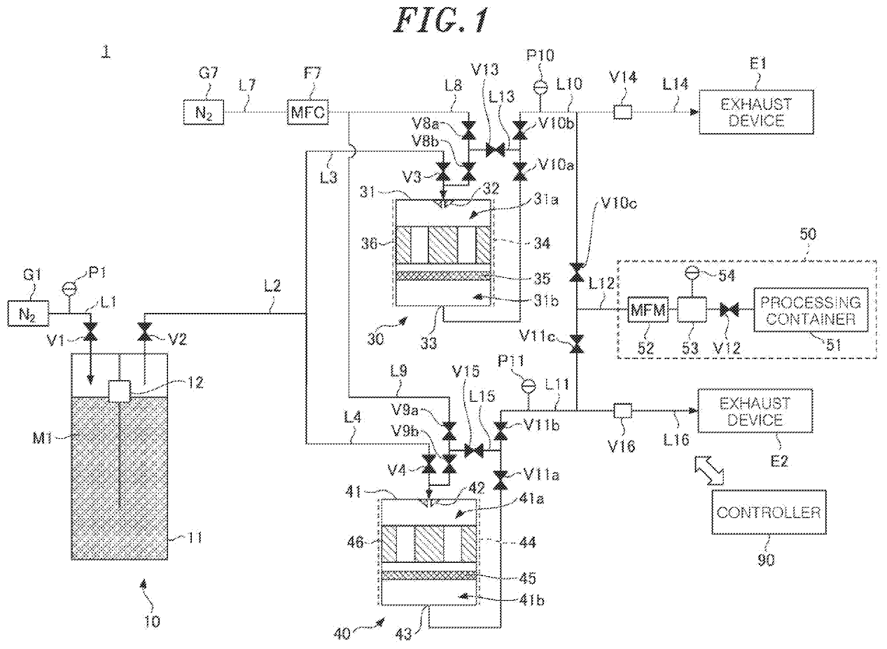

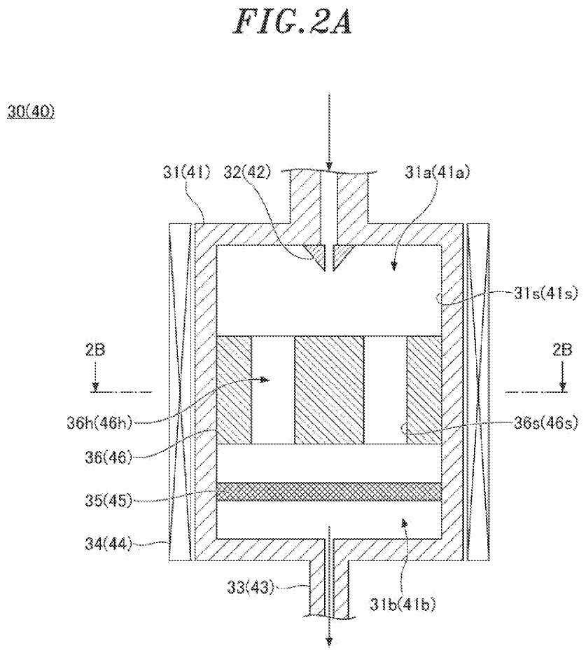

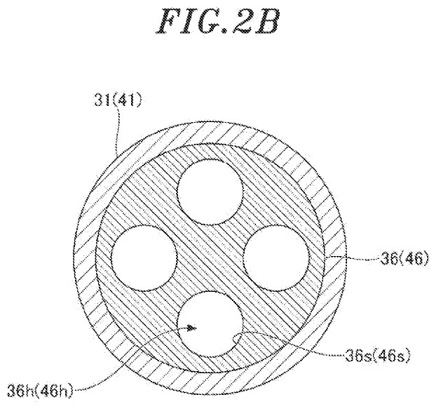

A raw material supply system according to an embodiment will be described with reference to FIGS. 1, 2A, and 2B.

A raw material supply system 1 is a system for producing a reactive gas by sublimating a second solid raw material formed by removing a solvent from a solution (hereinafter, also simply referred to as “solution”) in which a first solid raw material is dissolved in the solvent, and performing film formation using the produced reactive gas in a processing apparatus.

The first solid raw material is not particularly limited, but may be, e.g., an organometallic complex containing a metal element such as strontium (Sr), molybdenum (Mo), ruthenium (Ru), zirconium (Zr), hafnium (Hf), tungsten (W), or aluminum (Al), or may be a chloride containing a metal element such as tungsten (W), aluminum (Al) or the like. The solvent may be any solvent as long as it can dissolve the first solid raw material to produce a solution, and may be, e.g., hexane.

The raw material supply system 1 includes a raw material supply source 10, raw material supply devices 30 and 40, a processing device 50, and a controller 90.

The raw material supply source 10 supplies solution M1 to the raw material supply devices 30 and 40. The raw material supply source 10 is disposed in a subfab, for example. In the present embodiment, the raw material supply source 10 includes a tank 11 and a float sensor 12. The tank 11 is filled with the solution M1. The float sensor 12 detects the amount of the solution M1 filled in the tank 11.

One end of a line L1 is inserted into the raw material supply source 10 from the position above the tank 11. The other end of the line L1 is connected to a carrier gas supply source G1, so that a carrier gas is supplied from the supply source G1 into the tank 11 via the line L1. The carrier gas may be, e.g., an inert gas such as nitrogen (N₂), argon (Ar), or the like. A valve V1 is disposed in the line L1. When the valve V1 is opened, the carrier gas is supplied from the supply source G1 to the raw material supply source 10. When the valve V1 is closed, the supply of the carrier gas from the supply source G1 to the raw material supply source 10 is blocked. The line L1 is provided with a pressure sensor P1 for detecting a pressure in the line L1. The detection value of the pressure sensor P1 is transmitted to the controller 90. Further, the line L1 may be provided with a flow rate controller (not shown) for controlling the flow rate of the carrier gas flowing through the line L1, an additional valve, or the like.

The raw material supply source 10 is connected to the raw material supply device 30 through lines L2 and L3, and supplies the solution M1 to the raw material supply device 30 through the lines L2 and L3. Valves V2 and V3 are disposed in the lines L2 and L3, respectively. When the valves V2 and V3 are opened, the solution M1 is supplied from the raw material supply source 10 to the raw material supply device 30. When the valves V2 and V3 are closed, the supply of the solution M1 from the raw material supply source 10 to the raw material supply device 30 is blocked. Further, a line L3 may be provided with a flow rate controller (not shown) for controlling the flow rate of the solution M1 flowing through the line L3, an additional valve, or the like.

Further, the raw material supply source 10 is connected to the raw material supply device 40 through lines L2 and L4, and supplies the solution M1 to the raw material supply device 40 through the lines L2 and L4. A valve V4 is disposed in the line L4. When the valves V2 and V4 are opened, the solution M1 is supplied from the raw material supply source 10 to the raw material supply device 40. When the valves V2 and V4 are closed, the supply of the solution M1 from the raw material supply source 10 to the raw material supply device 40 is blocked. Further, the line L4 may be provided with a flow rate controller (not shown) for controlling the flow rate of the solution M1 flowing through the line L4, an additional valve, or the like.

The raw material supply device 30 stores the solution M1 transferred from the raw material supply source 10. In the present embodiment, the raw material supply device 30 includes a container 31, an injection part 32, an exhaust port 33, a heating part 34, a filter 35, and a columnar body 36.

The container 31 has an inner wall 31s forming an inner space, and stores the solution M1 transferred from the raw material supply source 10 in the inner space.

The injection part 32 sprays and injects the solution M1 supplied from the raw material supply source 10 through the lines L2 and L3 into the container 31. The injection part 32 sprays the solution M1 to be adhered as a mist raw material MM to the inside of the container 31 in a state where the solvent of the solution M1 is not removed. The injection part 32 may be, e.g., a spray nozzle. The spray nozzle is attached to the ceiling of the container 31. However, the spray nozzle may be attached to the sidewall of the container 31. Further, the spray nozzle may be attached to the ceiling of the container 31 such that the direction of the nozzle center axis can be changed.

The exhaust port 33 is disposed below the container 31 to exhaust the container 31. The processing device 50 is connected to the exhaust port 33 through lines L10 and L12. Further, an exhaust device E1 is connected to the exhaust port 33 through lines L10 and L14.

The heating part 34 includes a heater disposed to cover the outer periphery of the container 31. However, the heating part 34 may include a heater disposed at the bottom portion or the ceiling of the container 31. The heating part 34 heats the container 31 to various temperatures, such as a spraying temperature, a drying temperature, and a sublimation temperature. The spraying temperature is a temperature at which the solution M1 sprayed into the container 31 from the injection part 32 can be deposited as the mist raw material MM in the container 31. The drying temperature is a temperature at which the solvent can be removed from the mist raw material MM adhered to the container 31 to form a solid raw material. The drying temperature is determined depending on the vapor pressure of the solvent contained in the mist raw material MM, for example. Hereinafter, the solid raw material formed by removing the solvent from the mist raw material MM will be referred to as “second solid raw material.” The sublimation temperature is a temperature at which the second solid raw material can be sublimed to produce a reactive gas. The sublimation temperature is determined depending on the vapor pressure of the second solid raw material, for example. The spraying temperature, the drying temperature, and the sublimation temperature may satisfy the following magnitude relationship the spraying temperature<the drying temperature<the sublimation temperature.

The filter 35 is disposed substantially horizontally in the container 31, and partitions the container 31 into a first region 31a and a second region 31b. The injection part 32 is disposed in the first region 31a. The second region 31b is disposed below the first region 31a. The exhaust port 33 is disposed in the second region 31b. The filter 35 is made of a material that transmits the reactive gas and captures the mist raw material MM, the second solid raw material, and impurities such as particles. Accordingly, the solution M1 sprayed from the injection part 32 can be prevented from flowing out of the container 31 through the exhaust port 33. The filter 35 is made of, e.g., a porous material. The porous material may be a porous metal material such as a stainless-steel sintered body, or a porous ceramic material. Further, the filter 35 may not be provided.

The columnar body 36 is disposed below the injection part 32 in the first region 31a. The columnar body 36 is formed separately from the container 31. However, the columnar body 36 may be formed integrally with the container 31. The columnar body 36 has a cylindrical shape with its axis extending in a vertical direction, and the outer wall surface thereof is bonded to the inner wall 31s of the container 31. The columnar body 36 is made of, e.g., stainless steel, aluminum, or nickel alloy.

The columnar body 36 has a plurality of (e.g., four) through-holes 36h penetrating in the axial direction. The plurality of through-holes 36h are formed at intervals along the circumferential direction of the columnar body 36, for example. The solution M1 sprayed from the injection part 32 is adhered as the mist raw material MM to the inner wall surfaces 36s of the through-holes 36h. The amount of the mist raw material MM adhered to the inside of the container 31 increases as the surface area in the container 31 increases. Therefore, it is preferable that the columnar body 36 has the plurality of through-holes 36h. However, there may be one through-hole 36h.

Each through-hole 36h has a circular shape in plan view. However, each through-hole 36h may have a polygonal shape in plan view. Each through-hole 36h has a through-axis parallel to the vertical direction. However, the through-axis of each through-hole 36h may be inclined with respect to the vertical direction. When the through-axis of each through-hole 36h is inclined, the surface area of the inner wall surface 36s becomes greater than that in the case where the through-axis of each through-hole 36h is not inclined, which results in an increase in the amount of the mist raw material MM adhered to the inner wall surface 36s. It is preferable that the inner wall surface 36s has fine irregularities. Accordingly, the surface area of the inner wall surface 36s increases, so the amount of the mist raw material MM adhered to the inner wall surface 36s increases. The irregularities are formed by, e.g., blasting.

One end of a line L8 is connected to the downstream side of the valve V3 of the line L3. The other end of the line L8 is connected to a carrier gas supply source G7 through a line L7. The carrier gas is supplied from the supply source G7 into the container 31 through the lines L7, L8, and L3. The carrier gas may be an inert gas such as N₂, Ar, or the like. Valves V8a and V8b are sequentially disposed in the line L8 from the supply source G7 side. When the valves V8a and V8b are opened, the carrier gas is supplied from the supply source G7 to the raw material supply device 30. When the valves V8a and V8b are closed, the supply of the carrier gas from the supply source G7 to the raw material supply device 30 is blocked. A flow rate controller F7 is disposed in the line L7 to control the flow rate of the carrier gas flowing through the line L7. In the present embodiment, the flow rate controller F7 is a mass flow controller (MFC).

The raw material supply device 30 is connected to the processing device 50 through the lines L10 and L12, and supplies a reactive gas to the processing device 50 through the lines L10 and L12. Valves V10a to V10c are sequentially disposed in the line L10 from the raw material supply device 30 side. When the valves V10a to V10c are opened, the reactive gas is supplied from the raw material supply device 30 to the processing device 50. When the valves V10a to V10c are closed, the supply of the reactive gas from the raw material supply device 30 to the processing device 50 is blocked. The line L10 is provided with a pressure sensor P10 for detecting a pressure in the line L10. The detection value of the pressure sensor P10 is transmitted to the controller 90.

One end of a line L13 is connected between the valve V10a and the valve V10b of the line L10. The other end of the line L13 is connected between the valve V8a and the valve V8b of the line L8. The line L13 functions as a bypass line that connects the line L8 and the line L10 without passing through the raw material supply device 30. A valve V13 is disposed in the line L13. When the valve V13 is opened, the line L8 and the line L10 communicate with each other. When the valve V13 is closed, the communication between the line L8 and the line L10 is blocked.

One end of a line L14 is connected between the valve V10b and the valve V10c of the line L10. The other end of the line L14 is connected to the exhaust device E1, e.g., a vacuum pump or the like. A pressure control valve V14 is disposed in the line L14. When the pressure control valve V14 is opened in a state where the valves V10a and V10b are opened, the container 31 is exhausted, and the removal of the solvent from the mist raw material MM adhered to the inside of the container 31 can be promoted. Further, the pressure in the container 31 can be controlled by adjusting the opening degree of the pressure control valve V14.

The raw material supply device 40 stores the solution M1 transferred from the raw material supply source 10. The raw material supply device 40 is disposed in parallel with the raw material supply device 30. In the present embodiment, the raw material supply device 40 includes a container 41, an injection part 42, an exhaust port 43, a heating part 44, a filter 45, and a columnar body 46.

The container 41 has an inner wall 41s forming an inner space, and stores the solution M1 transferred from the raw material supply source 10 in the inner space.

The injection part 42 sprays and injects the solution M1 supplied from the raw material supply source 10 through the lines L2 and L4 into the container 41. The injection part 42 sprays the solution M1 to be adhered as the mist raw material MM to the inside of the container 41 in a state where the solvent of the solution M1 is not removed. The injection part 42 may have the same configuration as that of the injection part 32, for example.

The exhaust port 43 is disposed below the container 41 to exhaust the container 41. The processing device 50 is connected to the exhaust port 43 through lines L11 and L12. Further, an exhaust device E2 is connected to the exhaust port 43 through lines L11 and L16.

The heating part 44 includes a heater disposed to cover the outer periphery of the container 41. However, the heating part 44 may include a heater disposed at the bottom portion or the ceiling of the container 41. The heating part 44 heats the container 41 to various temperatures, such as a spraying temperature, a drying temperature, and a sublimation temperature, for example, similarly to the heating part 34.

The filter 45 is disposed substantially horizontally in the container 41, and partitions the container 41 into a first region 41a and a second region 41b. The injection part 42 is disposed in the first region 41a. The second region 41b is disposed below the first region 41a. The exhaust port 43 is disposed in the second region 41b. The filter 45 is made of a material that transmits the reactive gas and captures the mist raw material MM, the second solid raw material, and impurities such as particles. Accordingly, the solution M1 sprayed from the injection part 42 can be prevented from flowing out of the container 41 through the exhaust port 43. The filter 45 is made of the same material as that of the filter 35, for example. Further, the filter 45 may not be provided.

The columnar body 46 is disposed below the injection part 42 in the first region 41a. The columnar body 46 may have the same configuration as that of the columnar body 36, for example.

One end of the line L9 is connected to the downstream side of the valve V4 of the line L4. The other end of the line L9 is connected to the carrier gas supply source G7 through the line L7, so that the carrier gas is supplied from the supply source G7 into the container 41 through the lines L7, L9, and L4. The carrier gas may be an inert gas such as N₂, Ar, or the like. Valves V9a and V9b are sequentially disposed in the line L9 from the supply source G7 side. When the valves V9a and V9b are opened, the carrier gas is supplied from the supply source G7 to the raw material supply device 40. When the valves V9a and V9b are closed, the supply of the carrier gas from the supply source G7 to the raw material supply device 40 is blocked.

The raw material supply device 40 is connected to the processing device 50 through the lines L11 and L12, and supplies a reactive gas to the processing device 50 through the lines L11 and L12. Valves V11a to V11c are sequentially disposed in the line L11 from the raw material supply device 40 side. When the valves V11a to V11c are opened, reactive gas is supplied from the raw material supply device 40 to the processing device 50. When the valves V11a to V11c are closed, the supply of the reactive gas from the raw material supply device 40 to the processing device 50 is blocked. The line L11 is provided with a pressure sensor P11 for detecting a pressure in the line L11. The detection value of pressure sensor P11 is transmitted to the controller 90.

One end of a line L15 is connected between the valve V11a and the valve V11b of the line L11. The other end of the line L15 is connected between the valve V9a and the valve V9b of the line L9. The line L15 functions as a bypass line that connects the line L9 and the line L11 without passing through the raw material supply device 40. A valve V15 is disposed in the line L15. When the valve V15 is opened, the line L9 and the line L11 are connected to each other. When the valve V15 is closed, the communication between the line L9 and the line L11 is blocked.

One end of a line L16 is connected between the valve V11b and the valve V11c of the line L11. The other end of the line L16 is connected to the exhaust device E2, e.g., a vacuum pump or the like. A pressure control valve V16 is disposed in the line L16. When the pressure control valve V16 is opened in a state where the valves V11a and V11b are opened, the container 41 is exhausted, and the removal of the solvent from the mist raw material MM adhered to the inside of the container 41 can be promoted. Further, the pressure in the container 41 can be controlled by adjusting the opening degree of the pressure control valve V16.

The processing device 50 is connected to the raw material supply device 30 through the lines L10 and L12, and the reactive gas produced by heating and sublimating the second solid raw material in the raw material supply device 30 is supplied to the processing device 50. Further, the processing device 50 is connected to the raw material supply device 40 through the lines L11 and L12, and the reactive gas produced by heating and sublimating the second solid raw material in the raw material supply device 40 is supplied to the processing device 50.

The processing apparatus 50 performs various treatments such as film formation and the like on a substrate such as a semiconductor wafer using the reactive gases supplied from the raw material supply devices 30 and 40. In the present embodiment, the processing device 50 includes a processing container 51, a flow meter 52, a storage tank 53, a pressure sensor 54, and a valve V12. The processing container 51 accommodates one or multiple substrates. In the present embodiment, the flow meter 52 is a mass flow meter (MFM). The flow meter 52 is disposed in the line L12 to measure the flow rate of the reactive gas flowing through the line L12. The storage tank 53 temporarily stores the reactive gas. Due to the presence of the storage tank 53, the reactive gas can be supplied at a large flow rate into the processing container 51 in a short period of time. The storage tank 53 is also referred to as “buffer tank” or “filling tank.” The pressure sensor 54 detects the pressure in storage tank 53. The pressure sensor 54 is, e.g., a capacitance manometer. The valve V12 is disposed in the line L12. When the valve V12 is opened, the reactive gas is supplied from the raw material supply devices 30 and 40 to the processing container 51. When the valve V12 is closed, the supply of the reactive gas from the raw material supply devices 30 and 40 to the processing container 51 is blocked.

The controller 90 is an example of a control part, and controls individual components of the raw material supply system 1. For example, the controller 90 controls the operations of the raw material supply source 10, the raw material supply devices 30 and 40, the processing device 50, and the like. Further, the controller 90 controls opening and closing of various valves. The controller 90 may be, e.g., a computer.

### Raw Material Supply Method

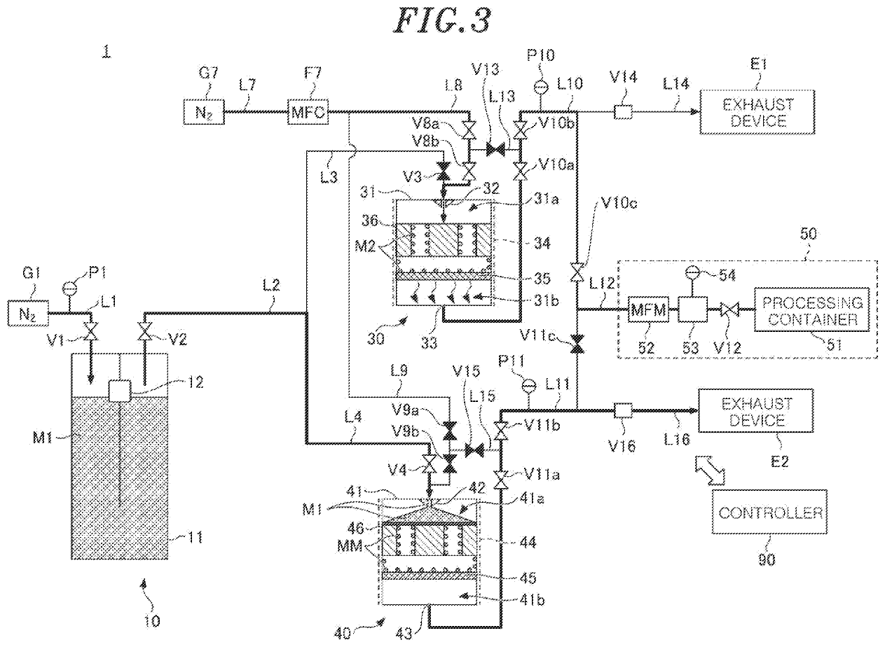

An example of a raw material supply method performed in the raw material supply system 1 will be described with reference to FIGS. 3 to 7. In the raw material supply system 1, the controller 90 controls the opening and closing of various valves, so that one of the two raw material supply devices 30 and 40 arranged in parallel supplies the reactive gas to the processing device 50 and the other one performs filling of the solid raw material. Hereinafter, an example of the operation of the raw material supply system 1 will be described in detail.

### (Supply of Reactive Gas by Raw Material Supply Device 30)

A case where the raw material supply device 30 supplies a reactive gas to the processing device 50 in the raw material supply system 1 will be described with reference to FIGS. 3 and 5 to 7. In this case, in the raw material supply system 1, the raw material supply device 40 performs the spraying process and the drying process, and the raw material supply device 30 performs the sublimation process.

In FIG. 3, the lines through which the carrier gas, the solution M1, and the reactive gas are flowing are indicated by thick solid lines, and the lines through which the carrier gas, the solution M1, and the reactive gas are not flowing are indicated by thin solid lines. Further, in FIG. 3, the open valve state is indicated in white, and a closed valve state is indicated in black. In the raw material supply system 1, in an initial state, it is assumed that all valves are closed, and the second solid raw material M2 is stored in the raw material supply device 30 as shown in FIG. 1.

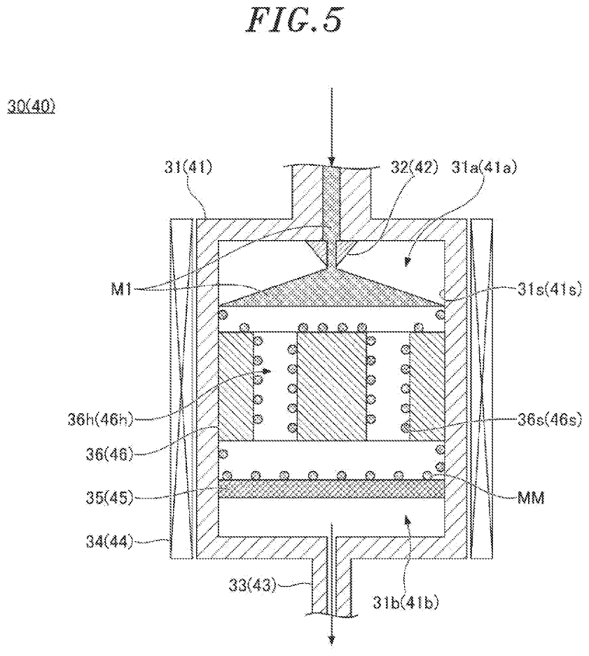

The spraying process is a process of spraying the solution M1 in which the first solid raw material is dissolved in a solvent into the container 41, and is a process of making the solution M1 adhered as the mist raw material MM to the inside of the container 41 in a state where the solvent of the solution M1 is not removed. For example, in the spraying process, the controller 90 opens the valves V1, V2, and V4. Accordingly, the carrier gas is supplied from the supply source G1 to the raw material supply source 10, and the solution M1 is transferred from the raw material supply source 10 to the raw material supply device 40 through the lines L2 and L4. Further, the controller 90 opens the valves V11a and V11b to adjust the opening degree of the pressure control valve V16. Hence, the container 41 is exhausted by the exhaust device E2, and the pressure in the container 41 is reduced to a first pressure. Further, the controller 90 controls the heating part 44 to heat the container 41 to the spray temperature. Accordingly, as shown in FIG. 5, the solution M1 that is transferred to the raw material supply device 40 and sprayed into the container 41 from the injection part 42 is adhered as the mist raw material MM to the inner wall 41s, the filter 45, and the inner wall surface 46s in a state where the solvent is not removed. In the spraying process, the pressure in the container 41 may not be reduced. However, it is preferable to reduce the pressure in the container 41 in the spraying process in order to adhere the mist raw material MM to a wider range of the inner wall 41s, the filter 45, and the inner wall surface 46s.

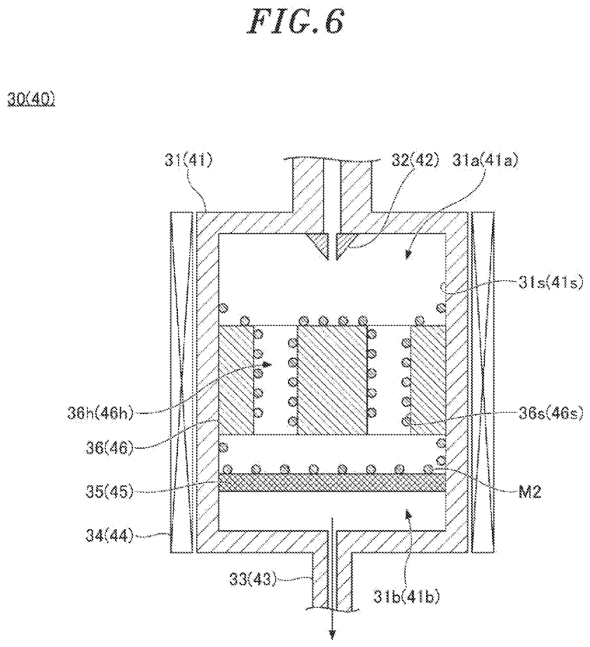

The drying process is performed subsequent to the spraying process. The drying process is a process of forming the second solid raw material M2 by removing the solvent from the mist raw material MM adhered to the inner wall 41s, the filter 45, and the inner wall surface 46s. For example, in the drying process, the controller 90 closes the valves V1, V2, and V4. Accordingly, the supply of the solution M1 from the raw material supply source 10 into the container 41 is stopped. Further, the controller 90 reduces the pressure in the container 41 to a second pressure by adjusting the opening degree of the pressure control valve V16 while maintaining the open state of the valves V11a and V11b, and controls the heating part 44 to heat the container 41 to the drying temperature. Accordingly, as shown in FIG. 6, the solvent is removed from the mist raw material MM adhered to the inner wall 41s, the filter 45, and the inner wall surface 46s to form the second solid raw material M2, and the solvent removed from the mist raw material MM is exhausted by the exhaust device E2. Since the mist raw material MM is adhered to a wide range of the inner wall 41s, the filter 45, and the inner wall surface 46s in the spraying process, the second solid raw material M2 is formed over a wide area of the inner wall 41s, the filter 45, and the inner wall surface 46s after the solvent is removed from the mist raw material MM in the draying process. The second pressure may be lower than the first pressure, for example. Further, the drying temperature is a temperature higher than the spraying temperature, for example. However, if the solvent can be removed from the mist raw material MM by setting the second pressure to be lower than the first pressure, the drying temperature may be the same as the spraying temperature, for example.

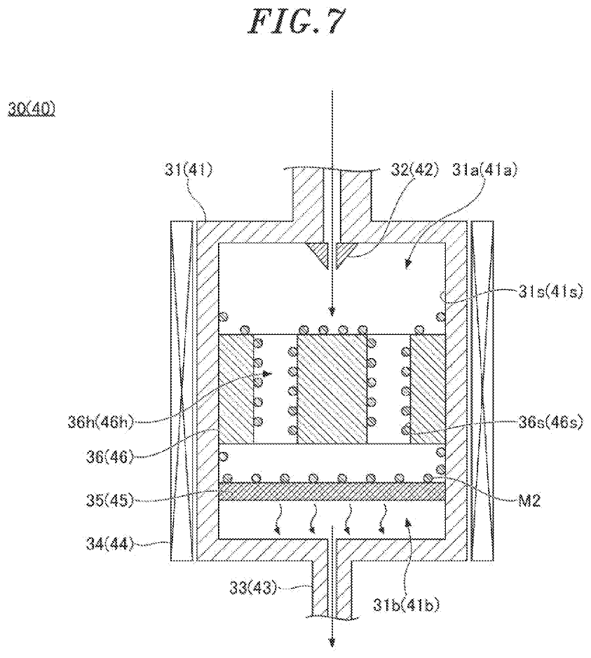

The sublimation process is a process in which the second solid raw material M2 formed in the container 31 is heated to sublimate the second solid raw material M2 and produce a reactive gas. For example, in the sublimation process, the controller 90 controls the heating part 34 to heat the container 31 to the sublimation temperature. Accordingly, as shown in FIG. 7, the second solid raw material M2 formed on the inner wall 31s, the filter 35, and the inner wall surface 36s is sublimated to produce a reactive gas. Further, the controller 90 opens the valves V8a, V8b, V10a to V10c, and V12. Thus, the carrier gas is injected into the container 31 from the supply source G7 through the lines L7 and L8, and the reactive gas produced in the container 31 together with the carrier gas is supplied to the processing container 51 through the lines L10 and L12. Since the second solid raw material M2 is formed over a wide area of the inner wall 31s, the filter 35, and the inner wall surface 36s in the drying process, the specific surface area of the second solid raw material M2 is large in the sublimation process. Accordingly, the speed at which the second solid raw material M2 sublimates can be increased. Hence, the reactive gas can be supplied at a large flow rate to the processing container 51. The sublimation temperature is a temperature higher than the drying temperature, for example.

### (Supply of Reactive Gas by Raw Material Supply Device 40)

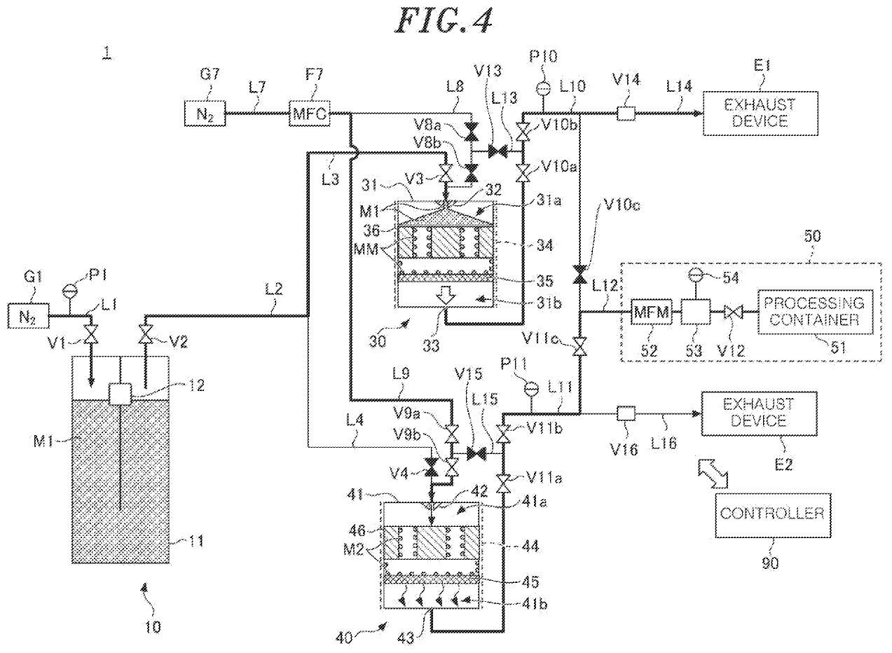

A case where the raw material supply device 40 supplies a reactive gas to the processing device 50 in the raw material supply system 1 will be described with reference to FIGS. 4 to 7. In this case, in the raw material supply system 1, the raw material supply device 30 performs the spraying process and the drying process, and the raw material supply device 40 performs the sublimation process.

In FIG. 4, the lines through which the carrier gas, the solution M1, and the reactive gas are flowing are indicated by thick solid lines, and the lines through which the carrier gas, the solution M1, and the reactive gas are not flowing are indicated by thin solid lines. Further, in FIG. 4, an open valve state is indicated in white, and a closed valve state is indicated in black. Further, in the raw material supply system 1, in an initial state, it is assumed that all the valves are closed, and the second solid raw material M2 is stored in the raw material supply device 40 as shown in FIG. 1.

The spraying process is a process of spraying the solution M1 in which the first solid raw material is dissolved in a solvent into the container 31, and is a process of making the solution M1 adhered as the mist raw material to the inside of the container 31 in a state where the solvent of the solution M1 is not removed. In the spraying process, the controller 90 opens the valves V1, V2, and V3. Accordingly, the carrier gas is supplied from the supply source G1 to the raw material supply source 10, and the solution M1 is transferred from the raw material supply source 10 to the raw material supply device 30 through the lines L2 and L3. Further, the controller 90 opens the valves V10a and V10b and adjusts the opening degree of the pressure control valve V14. Accordingly, the container 31 is exhausted by the exhaust device E1, and the pressure in the container 31 is reduced to the first pressure. Further, the controller 90 controls the heating part 34 to heat the container 31 to the spray temperature. Hence, as shown in FIG. 5, the solution M1 that is transferred to the raw material supply device 30 and sprayed from the injection part 32 into the container 31 is adhered as the mist raw material MM to the inner wall 31s, the filter 35, and the inner wall surface 36s in a state where the solvent is not removed. As a result, the mist raw material MM is adhered to a wide range of the inner wall 31s, the filter 35, and the inner wall surface 36s. Further, in the spraying process, the pressure in the container 31 may not be reduced. However, it is preferable to reduce the pressure in the container 31 in the spraying process in order to adhere the mist raw material MM to a wider range of the inner wall 31s, the filter 35, and the inner wall surface 36s.

The drying process is performed subsequent to the spraying process. The drying process is a process of forming the second solid raw material M2 by removing the solvent from the mist raw material MM adhered to the inner wall 31s, the filter 35, and the inner wall surface 36s. For example, in the drying process, the controller 90 closes the valves V1, V2, and V3. Accordingly, the supply of the solution M1 from the raw material supply source 10 into the container 31 is stopped. Further, the controller 90 reduces the pressure in the container 31 to the second pressure by adjusting the opening degree of the pressure control valve V14 while maintaining the open state of the valves V10a and V10b, and controls the heating part 34 to heat the container 31 to the drying temperature. Accordingly, as shown in FIG. 6, the solvent is removed from the mist raw material MM adhered to the inner wall 31s, the filter 35, and the inner wall surface 36s to form the second solid raw material M2, and the solvent removed from the mist raw material MM is exhausted by the exhaust device E1. Since the mist raw material MM is adhered to a wide range of the inner wall 31s, the filter 35, and the inner wall surface 36s in the spraying process, the second solid raw material M2 is formed over a wide area of the inner wall 31s, the filter 35, and the inner wall surface 36s after the solvent is removed from the mist raw material MM in the drying process. The second pressure may be lower than the first pressure, for example. Further, the drying temperature is a temperature higher than the spraying temperature, for example. However, if the solvent can be removed from the mist raw material MM by setting the second pressure to be lower than the first pressure, the drying temperature may be the same as the spraying temperature, for example.

The sublimation process is a process in which the second solid raw material M2 formed in the container 41 is heated to sublimate the second solid raw material M2 and produce a reactive gas. For example, in the sublimation process, the controller 90 controls the heating part 44 to heat the container 41 to the sublimation temperature. Accordingly, as shown in FIG. 7, the second solid raw material M2 formed on the inner wall 41s, the filter 45, and the inner wall surface 46s is sublimated to produce a reactive gas. Further, the controller 90 opens the valves V9a, V9b, V11a to V11c, and V12. Hence, the carrier gas is injected into the container 41 from the supply source G7 through the lines L7 and L9, and the reactive gas produced in the container 41 together with the carrier gas is supplied to the processing container 51 through the lines L11 and L12. In the sublimation process, the second solid raw material M2 is formed over a wide range of the inner wall 41s, the filter 45, and the inner wall surface 46s in the drying process, so the specific surface area of the second solid raw material M2 is large. Thus, the speed at which the second solid raw material M2 sublimates can be increased. As a result, the reactive gas can be supplied at a large flow rate to the processing container 51. The sublimation temperature is a temperature higher than the drying temperature, for example.

As described above, in accordance with the embodiment, the controller 90 controls the opening and closing of the valves, so that one of the two raw material supply devices 30 and 40 supplies the reactive gas to the processing device 50 and the other one performs filling of the solid raw material. Accordingly, the raw material can be automatically replenished in the raw material supply devices 30 and 40, which makes it possible to improve the continuous operation performance of the processing device 50 and improve the operation rate of the processing device 50.

Further, in accordance with the embodiment, when the solution M1 is sprayed into the containers 31 and 41 from the injection parts 32 and 42 in the spraying process, the solution M1 is adhered as the mist raw material MM to the inner walls 31s and 41s, the filters 35 and 45, and the inner wall surfaces 36s and 46s in a state where the solvent of the solution M1 is not removed. Next, in the drying process, the solvent is removed from the mist raw material MM adhered to the inner walls 31s and 41s, the filters 35 and 45, and the inner wall surfaces 36s and 46s to form the second solid raw material M2. Next, in the sublimation process, the second solid raw material M2 formed on the inner walls 31s and 41s, the filters 35 and 45, and the inner wall surfaces 36s and 46s is sublimated to produce a reactive gas. In accordance with the embodiment, the mist raw material MM can be adhered to a wide range of the inner surfaces of the containers 31 and 41 in the spraying process, so that the second solid raw material M2 can be formed over a wide range of the inside of the containers 31 and 41 in the drying process. Therefore, the speed at which the second solid raw material M2 sublimates in the sublimation process can be increased. As a result, the reactive gas can be supplied to the processing container 51 at a large flow rate.

### Modification of Raw Material Supply Device

### (First Modification)

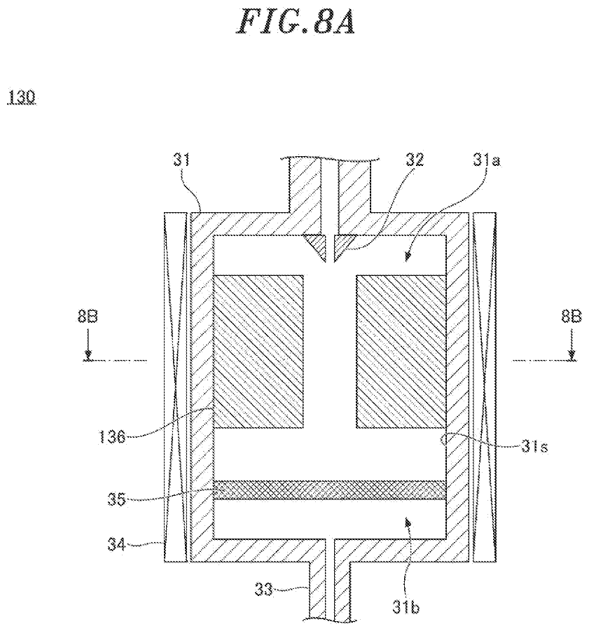

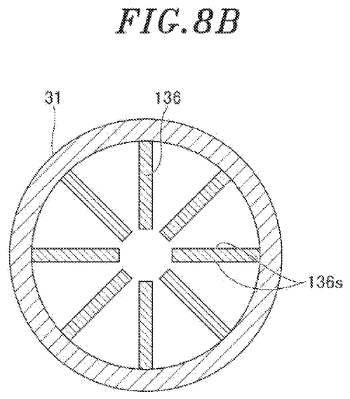

A first modification of the raw material supply device 30 will be described with reference to FIGS. 8A and 8B. FIG. 8A is a schematic cross-sectional view showing the first modification of the raw material supply device 30, and FIG. 8B is a cross-sectional view taken along a line 8B-8B of FIG. 8A.

The raw material supply device 130 of the first modification is different from the raw material supply device 30 in that it includes a plurality of (eight in the illustrated example) fins 136 instead of the columnar body 36. The other configurations may be the same as those of the raw material supply device 30. Hereinafter, the differences from the raw material supply device 30 will be mainly described.

The plurality of fins 136 are arranged radially in the first region 31a in plan view. The solution M1 sprayed from the injection part 32 is adhered as the mist raw material MM to plate surfaces 136s of the plurality of fins 136. The amount of the mist raw material MM adhered to the inside of the container 31 increases as the surface area in the container 31 increases. Therefore, it is preferable that the plurality of fins 136 are provided. However, there may be one fin 136.

Each fin 136 is formed separately from the container 31. However, each fin 136 may be formed integrally with the container 31. Each fin 136 has a plate shape in which a base end is bonded to the inner wall 31s of the container 31 and a tip end extending from the inner wall 31s of the container 31 toward the center of the container 31. Each fin 136 is bonded to the inner wall 31s of the container 31 such that the plate surface 136s becomes parallel to the vertical direction. However, each fin 136 may be bonded to the inner wall 31s of the container 31 such that the plate surface 136s becomes inclined with respect to the vertical direction. Each fin 136 is made of, e.g., stainless steel, aluminum, or nickel alloy.

It is preferable that the plate surface 136s has minute irregularities. Accordingly, the surface area of the plate surface 136s increases, and the amount of mist raw material MM adhered to the plate surface 136s increases. The irregularities are formed by, e.g., blasting.

In accordance with the raw material supply device 130, in the spraying process, when the solution M1 is sprayed into the container 31 from the injection part 32, the solution M1 is adhered as the mist raw material MM to the inner wall 31s, the filter 35, and the plate surface 136s in a state where the solvent of the solution M1 is not removed. Next, in the drying process, the solvent is removed from the mist raw material MM adhered to the inner wall 31s, the filter 35, and the plate surface 136s to form the second solid raw material M2. Next, in the sublimation process, the second solid raw material M2 formed on the inner wall 31s, the filter 35, and the plate surface 136s is sublimated to produce a reactive gas. In accordance with the raw material supply device 30 of the first modification, the mist raw material MM can be adhered to a wide range of the inside of the container 31 in the spraying process, so that the second solid raw material M2 is formed over a wide range of the inside of the container 31 during the drying process. Therefore, the speed at which the second solid raw material M2 sublimates in the sublimation process can be increased. As a result, the reactive gas can be supplied at a large flow rate to the processing container 51.

Although the raw material supply device 130, which is the first modification of the raw material supply device 30, has been described in FIGS. 8A and 8B, the raw material supply device 40 may have the same configuration.

### (Second Modification)

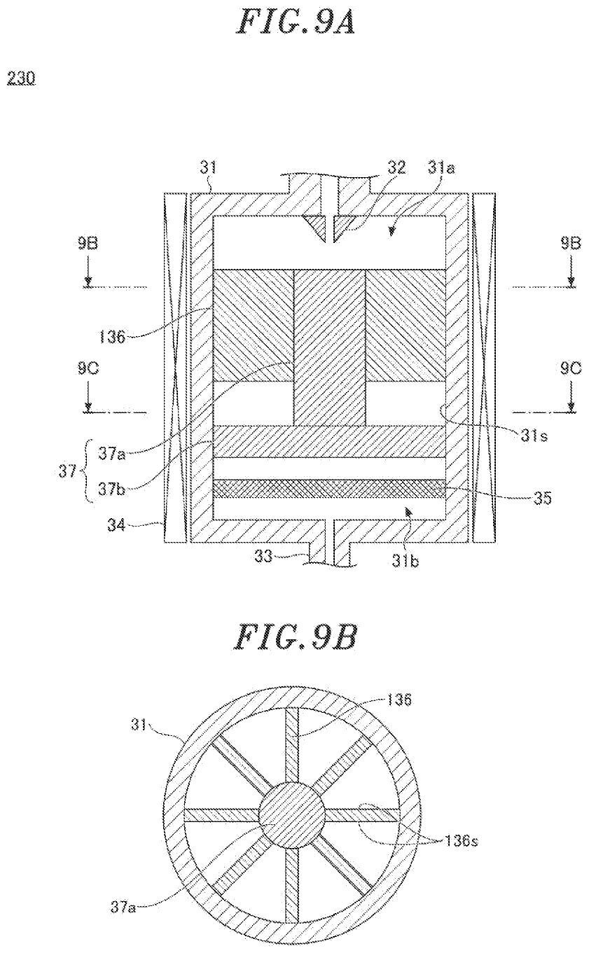

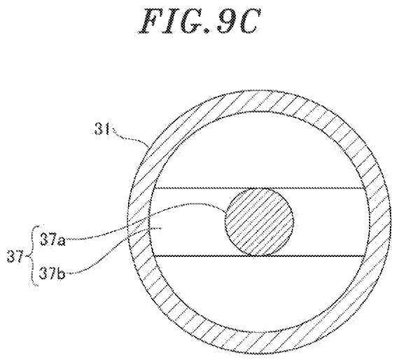

A second modification of the raw material supply device will be described with reference to FIGS. 9A, 9B, and 9C. FIG. 9A is a schematic cross-sectional view showing the second modification of the raw material supply device. FIG. 9B is a cross-sectional view taken along a line 9B-9B of FIG. 9A. FIG. 9C is a cross-sectional view taken along a line 9C-9C of FIG. 9A.

The raw material supply device 230 of the second modification is different from the raw material supply device 130 of the first modification in that it further includes a heat transfer part 37. The other configurations may be the same as those of the raw material supply device 130. Hereinafter, the differences from the raw material supply device 130 will be mainly described.

The heat transfer part 37 includes a shaft member 37a and a plate-shaped member 37b. The shaft member 37a has a cylindrical shape, and the outer wall surface thereof is bonded to the tip ends of the plurality of fins 136. In the plate-shaped member 37b, a plate surface has a plate shape parallel to the horizontal direction, and the upper plate surface is bonded to the lower end of the shaft member 37a. In the heat transfer part 37, the tip ends of the plurality of fins 136 and the inner wall 31s of the container 31 are connected by the shaft member 37a and the plate-shaped member 37b. The shaft member 37a and the plate-shaped member 37b are made of a thermally conductive material such as stainless steel, aluminum, or nickel alloy. Hence, the heat transfer part 37 transfers heat between the tip ends of the plurality of fins 136 and the inner wall 31s of the container 31 via the shaft member 37a and the plate-like member 37b.

The materials of the shaft member 37a and the plate-shaped member 37b may be the same as those of the fin 136, for example. In this case, even if a temperature change (heat cycle) occurs due to the repetition of the spraying process, the drying process, and the sublimation process, damages occurring at the bonding portions of the members due to the difference in the thermal expansion coefficient can be prevented because the fins 136, the shaft member 37a, and the plate-shaped member 37b have the same thermal expansion coefficient.

Further, the materials of the shaft member 37a and the plate-shaped member 37b may have higher thermal conductivity compared to the materials of the fin 136, for example. In this case, heat is efficiently transferred between the tip ends of the plurality of fins 136 and the inner wall 31s of the container 31, so that the tip ends of the plurality of fins 136 are efficiently heated. For example, when stainless steel or nickel alloy is used for the plurality of fins 136, aluminum can be used for the shaft member 37a and the plate-shaped member 37b.

Since the raw material supply device 230 includes the plurality of fins 136 similarly to the raw material supply device 130, the speed at which the second solid raw material M2 sublimates in the sublimation process can be increased and, accordingly, the reaction gas can be supplied at a large flow rate to the processing container 51.

Further, the raw material supply device 230 includes the heat transfer part 37 that connects the tip ends of the plurality of fins 136 and the inner wall 31s and transfers heat between the tip ends and the inner wall 31s. Hence, heat is transferred between the tip ends of the plurality of fins 136 and the inner wall 31s via the heat transfer part 37, and the tip ends of the plurality of fins 136 are heated. Accordingly, the uniformity of temperature in the surface direction of the plate surface 136s of each fin 136 is improved. As a result, in the spraying process, the mist raw material MM is uniformly adhered in the surface direction of the plate surface 136s of each fin 136.

Although the raw material supply device 230, which is the second modification example of the raw material supply device 30, has been described in FIGS. 9A, 9B, and 9C, the raw material supply device 40 may have the same configuration.

In the above embodiment, the columnar bodies 36 and 46 and the fins 136 are examples of the wall structure, the inner wall 31s is an example of a first wall surface, and the inner wall surfaces 36s and 46s and the plate surface 136s are examples of a second wall structure.

It should be noted that the embodiments of the present disclosure are illustrative in all respects and are not restrictive. The above-described embodiments may be omitted, replaced, or changed in various forms without departing from the scope of the appended claims and the gist thereof.

In the above embodiment, the case where the raw material supply system 1 includes two raw material supply devices 30 and 40 arranged in parallel has been described, but the present disclosure is not limited thereto. For example, there may be one raw material supply device, or three or more raw material supply devices may be arranged in parallel. However, it is preferable that the number of the raw material supply devices is two or more in order to eliminate downtime for filling the solution M1.

In the above embodiment, the case where the injection parts 32 and 42 are spray nozzles has been described, but the present disclosure is not limited thereto. For example, the injection parts 32 and 42 may be sprinkling nozzles for sprinkling and injecting the solution M1 into the containers 31 and 41.

In the above embodiment, the system for producing a reactive gas by sublimating the second solid raw material M2 formed by removing the solvent from the solution M1 and performing film formation using the produced reactive gas in the processing apparatus 50 has been described. However, the present disclosure is not limited thereto. For example, a dispersion such as slurry in which the first solid raw material is dispersed in a dispersion medium, colloidal solution in which the first solid raw material is dispersed in a dispersion medium, or the like may be used instead of the solution M1. For example, by using colloidal solution, a higher-concentration precursor can be filled compared to the case of using the solution M1 or slurry. The dispersion includes slurry and colloid as subordinate concepts. The slurry is also referred to as “suspension.” The colloid includes colloidal solution as a subordinate concept. The colloidal solution is also referred to as “sol.”

This application claims priority to Japanese Patent Application No. 2021-146294 filed on Sep. 8, 2021, the entire contents of which are incorporated herein by reference.

### DESCRIPTION OF REFERENCE NUMERALS

30, 40: raw material supply device
31, 41: container
32, 42: injection part
36, 46: columnar body
136: fin

1. A raw material supply device for producing a reactive gas from a solution in which a solid raw material is dissolved in a solvent or from a dispersion system in which a solid raw material is dispersed in a dispersion medium, comprising:
a container having a first wall surface forming an inner space;
a spray nozzle configured to spray the solution or the dispersion system into the inner space; and
a wall structure disposed in the inner space and having a second wall surface extending in a vertical direction.

2. The raw material supply device of claim 1, wherein the wall structure is separate from the container.

3. The raw material supply device of claim 1, wherein the wall structure is integral with the container.

4. The raw material supply device of claim 1, wherein the wall structure includes a columnar body whose axial direction extends in a vertical direction, and the columnar body has a through-hole penetrating in the axial direction, and
the second wall surface is an inner wall surface of the through-hole.

5. The raw material supply device of claim 4, wherein irregularities are on the inner wall surface of the through-hole.

6. The raw material supply device of claim 4, wherein the through-hole has a through-axis parallel to the vertical direction.

7. The raw material supply device of claim 4, wherein the through-hole has a through-axis inclined with respect to the vertical direction.

8. The raw material supply device of claim 1, wherein the wall structure includes one or more plate-shaped fins extending from the first wall surface toward a center of the container.

9. The raw material supply device of claim 8, wherein irregularities are on plate surfaces of the one or more plate-shaped fins.

10. The raw material supply device of claim 9, wherein the plate surfaces of the one or more plate-shaped fins are parallel to the vertical direction.

11. The raw material supply device of claim 9, wherein the plate surfaces of the one or more plate-shaped fins are inclined with respect to the vertical direction.

12. The raw material supply device of claim 8, wherein the one or more plate-shaped fins are arranged radially.

13. The raw material supply device of claim 8, further comprising:
a heat transfer part that connects tip ends of the one or more plate-shaped fins and the first wall surface and transfers heat between the tip ends and the first wall surface.

14. The raw material supply device of claim 13, wherein the heat transfer part includes a plate-shaped member whose plate surface is parallel to a horizontal direction.

15. A raw material supply device for producing a reactive gas from a solution of a solid raw material dissolved in a solvent or from a dispersion system in which a solid raw material is dispersed in a dispersion medium, comprising:
a container having a first wall surface forming an inner space;
a spraying nozzle configured to spray the solution or the dispersion system into the inner space; and
a wall structure disposed in the inner space and having a second wall surface extending in a vertical direction.
